(19) United States
(12) Patent Application Publication
(10) Pub. No.: US 2026/0107398 A1
(43) Pub. Date: Apr. 16, 2026

(54) ELECTRONIC COMPONENT LIFTING MECHANISM

(71) Applicant: Applied Optoelectronics, Inc., Sugar Land, TX (US)

(72) Inventors: John McMillan, Lilburn, GA (US); William G. Mahoney, Suwanee, GA (US)

(21) Appl. No.: 19/356,632

(22) Filed: Oct. 13, 2025

Related U.S. Application Data
(60) Provisional application No. 63/706,962, filed on Oct. 14, 2024.

(51) Int. Cl. H05K 5/02

(52) U.S. Cl. CPC H05K 5/023; H05K 5/0286

(57) ABSTRACT

An electronic component lifting mechanism comprising a handle and one or more connectors. The handle has a central portion, a first end and a second end. The handle further has a longitudinal midplane. The one or more connectors pivotally couples to the first and second ends of the handle along a rotational axis and fixedly coupled to a top surface of an electronic component. The midplane of the handle contains the rotational axis. The handle is configured to move between a first position and a second position. The handle is in the first position when the angle between the top surface of the electronic component and the midplane of the handle is in the range of 70° to 100°. The handle is in the second position when the angle between the top surface of the electronic component and the midplane of the handle is in the range of -10° to 10°.

### CROSS-REFERENCE TO RELATED APPLICATIONS

The present application claims the benefit of the filing date of U.S. Provisional Application Ser. No. 63/706,962, filed October 14, 2024, the teachings of which are hereby incorporated herein in their entirety.

### TECHNICAL FIELD

The technical field relates to an electronic component lifting mechanism for an electronic component and more particularly, to an electronic component lifting mechanism for an electronic component of an electronic device, such as a hybrid fiber-coaxial (HFC) network component configured to facilitate the removal of the electronic component from a housing of the electronic device.

### BACKGROUND INFORMATION

Electronic devices are often used in a variety of environments, such as in a hybrid fiber coaxial (HFC) network delivering CATV services to subscriber locations. In such devices, electronic components (e.g., RF amplifiers or nodes) are accommodated inside a housing designed to protect the electronic components from environmental conditions. The housing generally includes a main housing portion and a hinged lid portion that allows access to the components inside the housing. The electronic devices may be suspended off the ground on a line between a utility pole and a subscriber location (e.g., a home, office building, etc.).

The electronic components may need to be removed from the housing, for example, to allow the components to be upgraded, replaced, and/or repaired. In some instances, two handles are provided along opposing edges of an electronic component to facilitate the removal of the electronic component from a housing of the electronic device. One concern with using the two handles to remove the electrical component from the housing, is that it requires a user to use two hands. Where a user may have to climb to dangerous heights to access the component suspended off the ground, using two hands may increase the danger and risk of injury to the user as it may reduce the user’s stability. Another concern with using two handles is that the handles may not be lifted evenly when removing the electrical component from the housing risking damage to any coaxial physical and/or electrical connectors (e.g., stingers) that may link the electrical component and the housing. Thus, there exists a need for a means of allowing a user to lift the electrical component from the housing with one hand while reducing the risk of damage to any physical and/or electrical connectors coaxially linking the electrical component and housing.

### BRIEF DESCRIPTION OF THE DRAWINGS

Objects, features, and advantages disclosed herein will be apparent from the following description of particular embodiments, as illustrated in the accompanying drawings in which like reference characters/descriptions refer to the same parts throughout the different views. The drawings are not necessarily to scale, emphasis instead being placed upon illustrating the principles disclosed herein. For purposes of clarity, not every component may be labeled in every drawing.

FIG. 1A is an illustration of an example embodiment of an electronic component lifting mechanism consistent with the present disclosure.

FIG. 1B is an enlarged section view of a connector shown in FIG. 1A consistent with the present disclosure.

FIG. 2A is an illustration of an example embodiment of an electronic component lifting mechanism where the handle is in a first position, consistent with the present disclosure.

FIG. 2B is an illustration of an example embodiment of an electronic component lifting mechanism where the handle is in a second position, consistent with the present disclosure.

FIG. 3A is a perspective view of an electronic device including a main housing portion, an electronic component, and an electronic component lifting mechanism consistent with the present disclosure.

FIG. 3B is a top view of an electronic device including a main housing portion, an electronic component, and an electronic component lifting mechanism consistent with the present disclosure.

FIG. 4 is a perspective view of the electronic device of FIGS. 3A & 3B where the electronic component has been removed from the housing.

FIG. 5 is a perspective view of the bottom surface of an electronic component consistent with the present disclosure.

FIG. 6 is a cross-section of a stinger consistent with the present disclosure.

FIG. 7 is a cross-section of an electronic device including a main housing portion, an electronic component and an electronic component lifting mechanism consistent with the present disclosure.

### DETAILED DESCRIPTION

The present disclosure is not limited in its application to the details of construction and the arrangement of components set forth in the following description or illustrated in the drawings. The examples described herein may be capable of other embodiments and of being practiced or being carried out in various ways. Also, the phraseology and terminology used herein is for the purpose of description and should not be regarded as limiting as such may be understood by one of skill in the art. Throughout the present description, like reference characters may indicate like structure throughout the several views, and such structure need not be separately discussed. Furthermore, any particular feature(s) of a particular exemplary embodiment may be equally applied to any other exemplary embodiment(s) of this specification as suitable. In other words, features between the various exemplary embodiments described herein are interchangeable, and not exclusive.

An electronic component lifting mechanism, consistent with the embodiments of the present disclosure, may include a handle and one or more connectors. The handle may include a central portion, a first end, and a second end. The one or more connectors may couple the first and second end of the handle to a top surface of an electronic component. The one or more connectors may be configured to allow the handle to rotate relative to the top surface of the electronic component from a first position to a second position. In the first position, a longitudinal midplane of the handle may be substantially perpendicular to the top surface of the electronic component. In the second position, a longitudinal midplane of the handle may be substantially parallel to the top surface of the electronic component. When the handle is in the second position, the maximum distance between the handle and the top surface of the electronic component may be less than the minimum distance between the top surface of the electronic component and an upper edge of the main housing portion. This allows a hinged lid portion of the electronic device to be secured over the main housing portion thereby securing the electronic component within the housing from the external environment. The handle may be positioned at a location on the top surface of the electronic component such that, when lifted, the electronic component remains at substantially the same angle relative to the main housing portion as the angle of the electronic component relative to the main housing portion when the electronic component is installed in the housing. Thus, a handle consistent with the present disclosure may be used to remove an electronic component such as an RF amplifier or node from a housing portion of electronic equipment in a hybrid fiber coaxial (HFC) network delivering CATV services to subscriber locations, using one hand while reducing the risk of damaging any coaxial electrical and/or physical connectors between the electronic component and the housing.

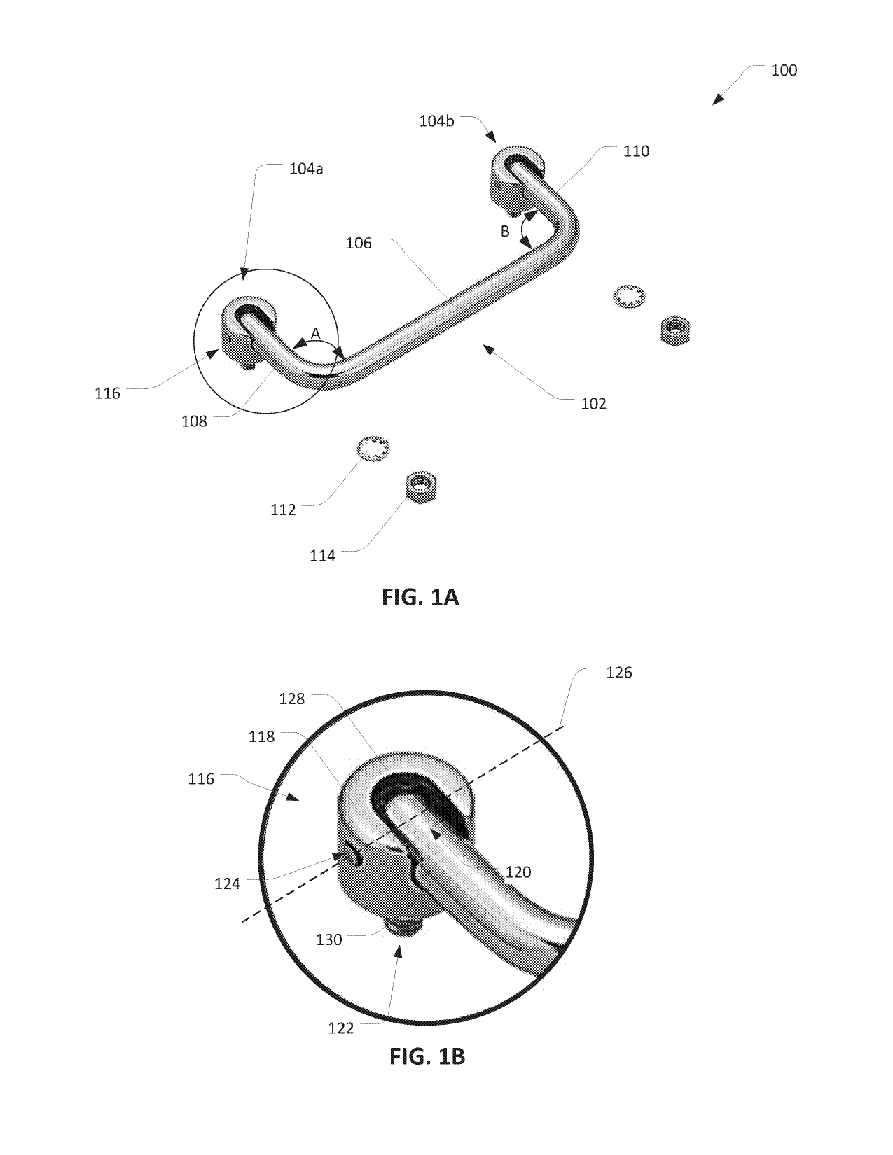

FIG. 1A illustrates one example embodiment of an electronic component lifting mechanism 100 consistent with the present disclosure. In general, the electronic component lifting mechanism 100 includes a handle 102 and two connectors 104a, 104b. The handle 102 includes a central portion 106 disposed between a first end 108 and a second end 110. The first end 108 extends from the central portion 106 at a non-zero angle A and is coupled to the connector 104a, and the second end 110 extends from the central portion 106 at non-zero angle B and is coupled to the connector 104b. The angle A between the central portion 106 and the first end 108 may be in the range of 45° to 135°, and, in some embodiments, in the range of 75° to 105°. Likewise, the non-zero angle B between the central portion 106 and the second end 108 may be in the range of 45° to 135°, and, in some embodiments, in the range of 75° to 105°. Additionally, while the angle A between the central portion 106 and the first end 108 and the angle B between the central portion 106 and the second end 110 in FIG. 1A appear equal, this should not be seen as a limitation of the present disclosure. Rather, the angle B between the central portion 106 and the second end 110 may be the same or differ from the angle A between the central portion 106 and the first end 108.

The handle may be configured to allow facile gripping by a user. In some embodiments, the central portion 106 of the handle 102 may have a length in the range of 5 inches (in) to 12 in, and, in some embodiments, in the range of 6 in to 10 in. The first and second ends 108, 110 may have a length in the range of 1 in to 5 in, and, in some embodiments in the range of 2 in to 3 in. Additionally, while the length of the first end 108 and the length of the second end 110 appear equal in FIG. 1A, this should not be seen as a limitation of the present disclosure. Rather, the lengths of the first end 108 and the second end 110 may be the same or different.

The connectors 104a, 104b may include a connection hub 116. In some embodiments, the connectors may include a retaining ring 112 and/or a nut 114. FIG. 1B depicts an enlarged view of the connector hub 116 of the example embodiment shown in FIG. 1A. Connector hub 116 includes a main body 118, a slot 120, a shaft 122 and a pin 124. The shaft 122 extends from a bottom surface of the main body 118. The shaft 122 may include one or more notches and/or threads configured to couple with the retaining ring 112 and/ or nut 114. As described more fully herein, the shaft 122 may be inserted through a hole in the top surface of the electronic component such that a portion of the shaft 122 protrudes beyond a bottom face of the top surface. The retaining ring 112 and/or nut 114 may be coupled to the threads and/or notches on the portion of shaft 122 protruding beyond the bottom face of the top surface such that the connector is fixedly coupled to the top surface of the electronic component.

An end 108, 110 of the handle 102 is coupled to the connector hub 116 within slot 120 by pin 124. The pin extends through aligned openings in the main body and the distal end of the end 108, 110 of the handle. The coupling of the connector hub and an end 108, 110 allows the handle 102 to pivot about a rotation axis 126 defined by the pin 124. The main body 118 provides a front stop 128 and back stop 130. The front stop 128 is configured to prevent the handle 102 from rotating beyond a first position and the back stop 130 is configured to prevent the handle 102 from rotating beyond a second position. When handle 102 is in first position, the end 108, 110 rests against the front stop surface 128. When handle 102 is in the second position, the end 108, 110 rests against the back stop surface 130.

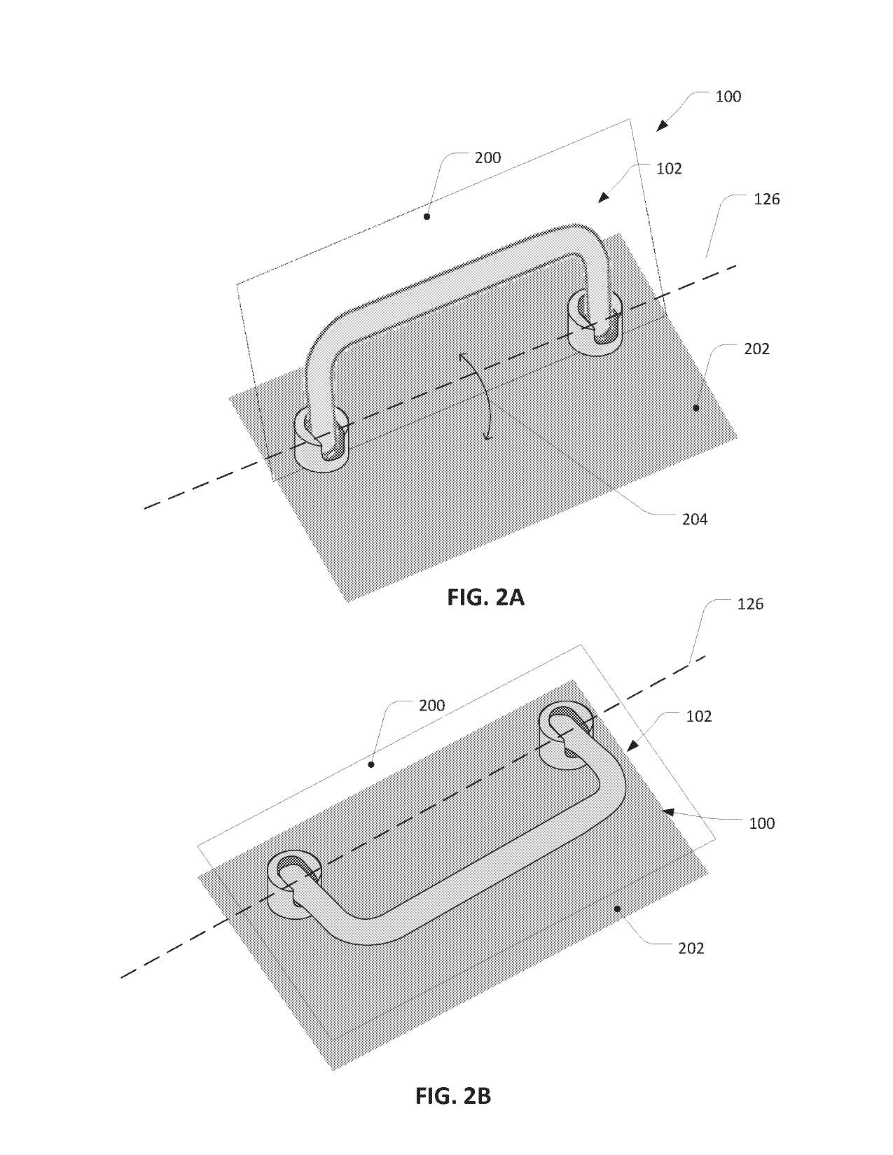

FIGS. 2A & 2B depict an example embodiment of handle 102 in the first position and the second position, respectively. Handle 102 has a longitudinal midplane 200 which longitudinally bisects the handle 102. In the illustrated example embodiment, the midplane 200 contains the rotational axis 126. In FIGS. 2A & 2B, the electronic component lifting mechanism 100 is installed on a top surface 202 of an electronic component. In the illustrated example embodiment, the midplane 200 is substantially perpendicular (e.g., within +/- 10 degrees) to the top surface 202 when the handle 102 is in the first position as shown in FIG. 1A. In some embodiments, when the handle 102 is in the first position, the midplane 200 may be at an angle 204 relative to the top surface 202 in the range of 70° to 120°, and, in some embodiments, in the range of 80° to 100°. Additionally, in the illustrated example embodiment the midplane 200 is substantially parallel (e.g., within +/- 10 degrees) to the top surface 202 when the handle 102 is in the second position as shown in FIG. 1B. In some embodiments, when the handle 102 is in the second position, the midplane 200 may be at an angle 204 relative to the top surface 202 in the range of -20° to 20°, and, in some embodiments, in the range of -10° to 10°

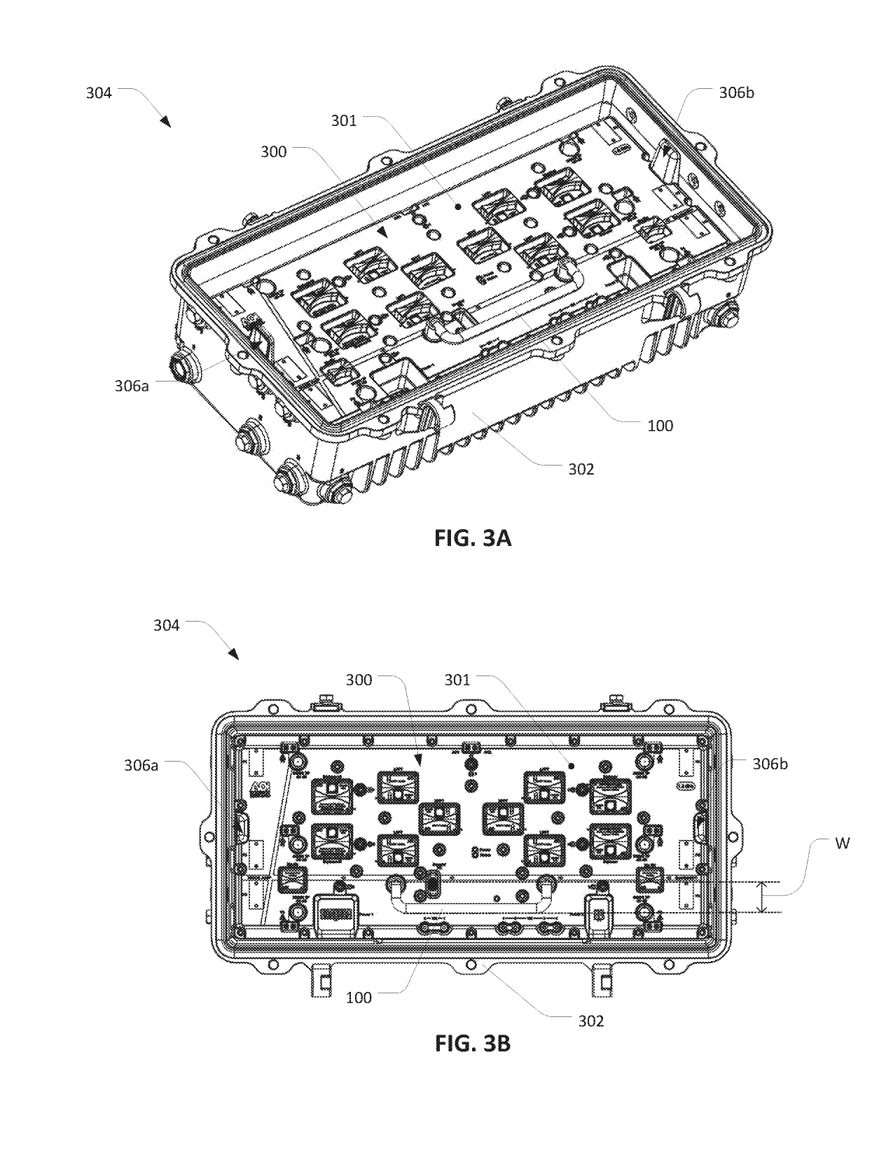

FIGS. 3A & 3B depict an example embodiment of the electronic component lifting mechanism 100 installed on a top surface 301 of an example electronic component 300. The electronic component 300 is installed in a main housing portion 302 of an electronic device 304. The electronic device 304 typically includes a hinged lid portion however, a hinged lid portion is not shown in FIG. 3 to allow visibility of the electronic component 300 within main housing portion 302. The electronic device 304 also includes pry features 306a, 306b.

Pry features 306a, 306b may have a base and wall projecting from the base. The base may be fixedly coupled to a top surface of the electronic component 301. The wall projecting from the base may extend from the base such that a portion of the wall projects above the upper edge of the main housing portion 302 when the electronic component 300 is installed therein. In the illustrated example embodiment of FIGS. 3A & 3B, the wall generally has a trapezoidal shape. Alternatively, the wall may have other shapes (e.g., rectangular, circular, triangular, or any other shape). The wall may provide a benching surface on which a tool (e.g., crowbar, screwdriver) can be used apply an upward force. The upward force on the benching surface may act to loosen the electronic component 300 from the main housing portion 302.

In the illustrated example embodiment of FIGS. 3A & 3B, the electronic device includes two pry features 306a, 306b, however, this should not be seen as a limitation of the present disclosure. The electronic device may include a quantity of pry features in the range of 1 to 10, more preferably in the range of 2 to 4. Additionally, the pry features 306a, 306b are depicted as located along opposing sides of the perimeter of the electronic component 300. This should not be seen as a limitation of the present disclosure, but rather the pry features may be located anywhere on the top surface of the electronic component 301. The electronic component lifting mechanism 100 may be located between the pry features 306a, 306b as depicted in FIGS. 3A & 3B.

The electronic component lifting mechanism 100 may have a width W where the width W is configured to prevent the handle 102, when in the second position, from extending beyond a lateral edge of the electronic component top surface 301 such that the handle 102 fits within the perimeter of the electronic component top surface 301.

The electronic component lifting mechanism 100 may be installed at a location on a top surface 301 of an electronic component 300 such that when a user lifts the electronic component 300 using the electronic component lifting mechanism 100, the weight of the electronic component 300 is evenly distributed. The weight of the electronic component 300 is evenly distributed where the electronic component 300 remains substantially level (i.e., where the top surface 301 is within +/- 10° of horizonal) when lifted by the electronic component lifting mechanism 100. In the illustrated example embodiment, the electronic component lifting mechanism is in centered between two opposing lateral edges of the electronic component top surface 301 and biased towards a third lateral edge perpendicular to the two opposing lateral edges. However, other locations of the electronic component lifting mechanism may be consistent with the present disclosure depending on the configuration of the electronic component 300.

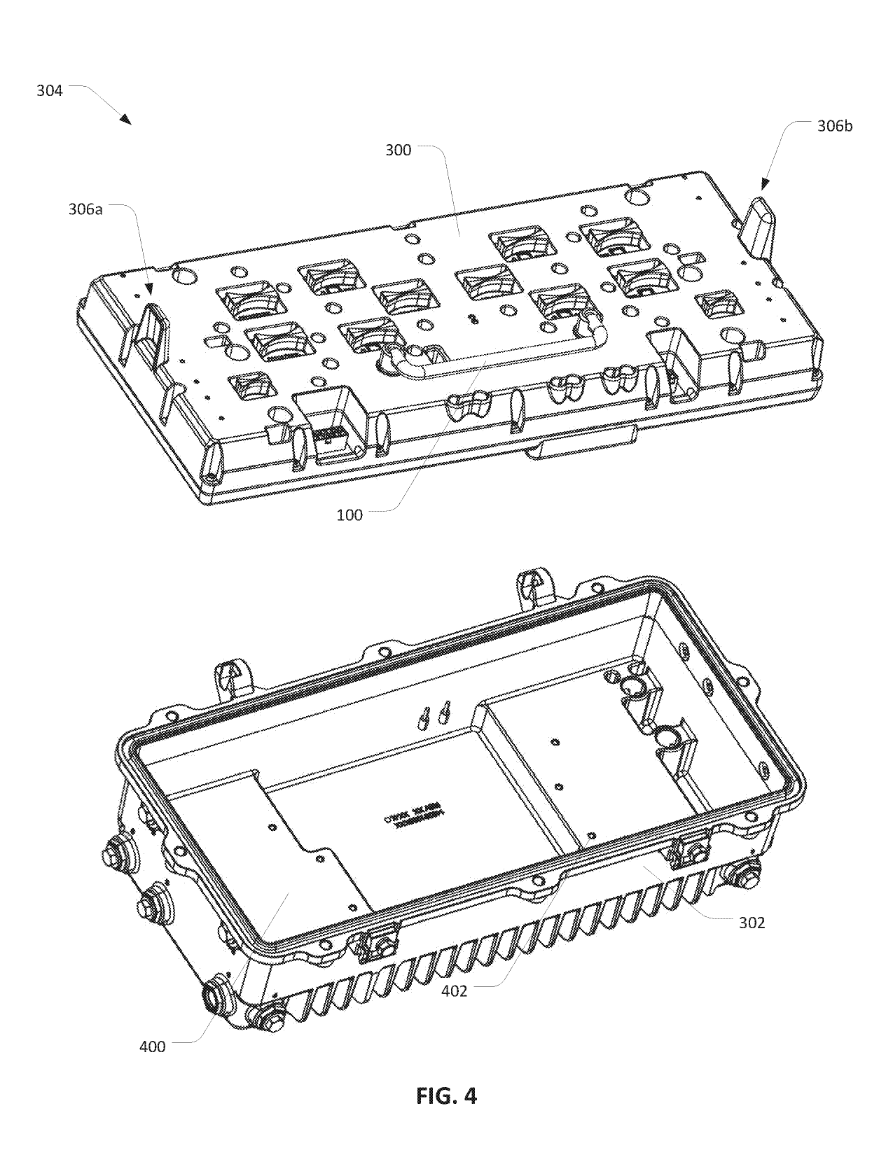

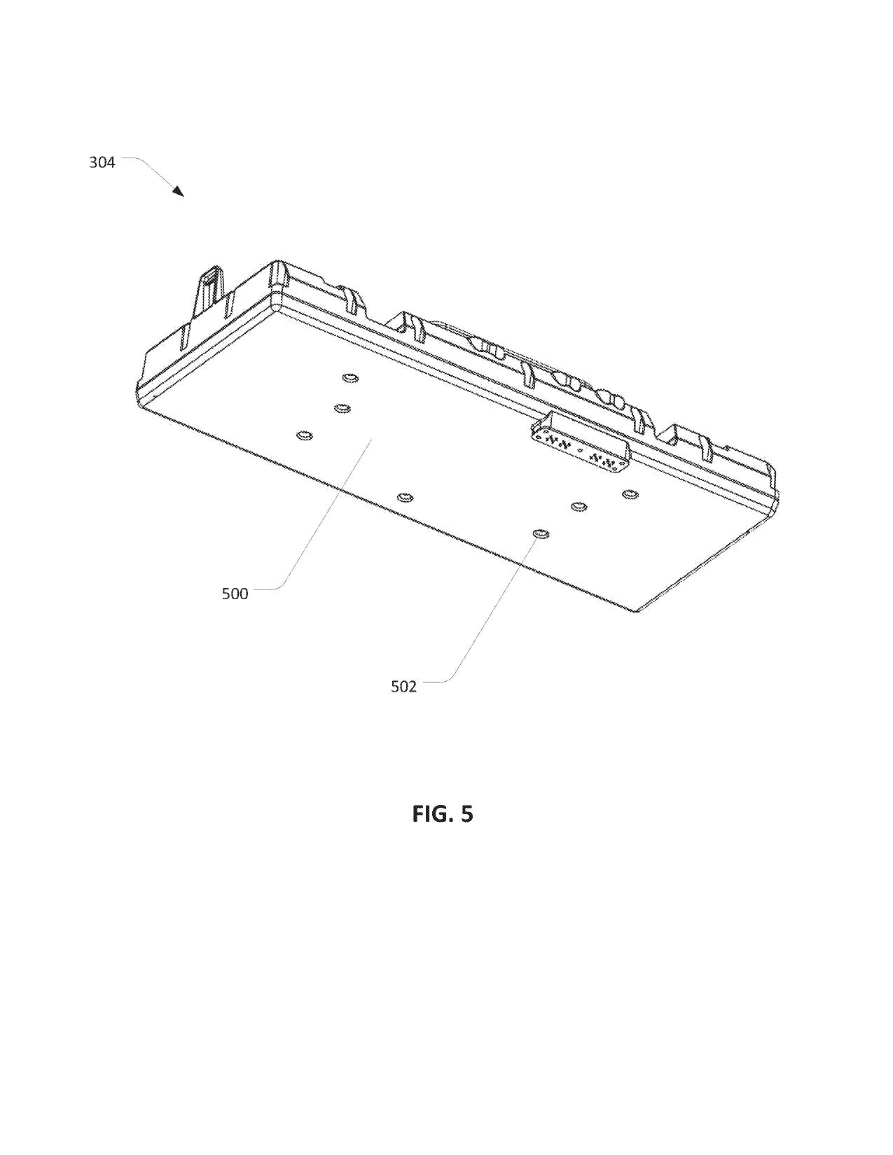

FIG. 4 depicts an exploded view of the electronic device 304 where the electronic component 300 is removed from the main housing portion 302. With electronic component 300 removed from the main housing portion 302, the bottom surface 400 of the main housing portion 302 is visible. Likewise, FIG. 5 depicts the bottom surface 500 of the electronic component 300. The main housing portion bottom surface 400 and the electronic component bottom surface 500 are coupled when the electronic component 300 is installed within the main housing portion 302.

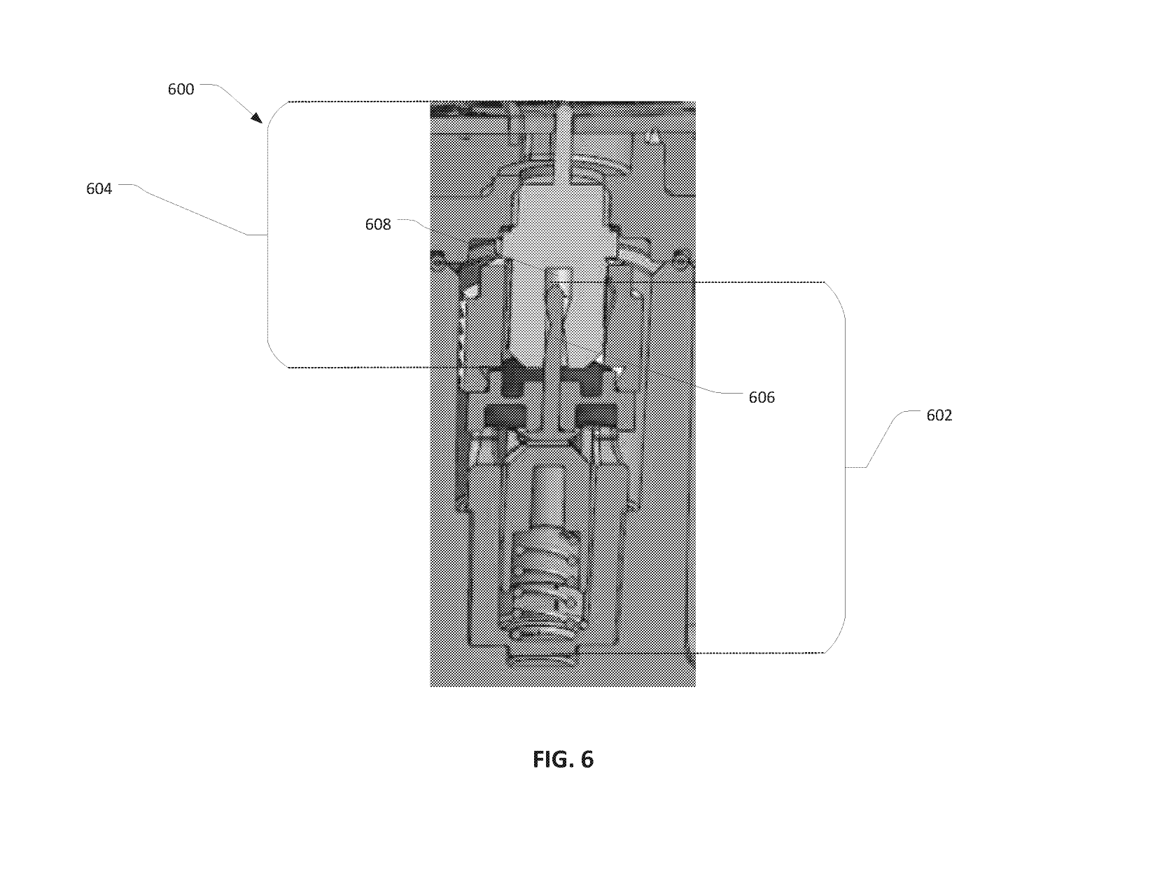

FIG. 6 illustrates an example of a coaxial connector, more specifically a stinger 600 consistent with the present invention. A stinger 600 may have a male portion 602 and a female portion 604. With reference also to FIGS. 4 and 5, the main housing portion bottom surface 400 and the electronic component bottom surface 500 may include one or more apertures 402, 502, respectively, configured to house a male portion 602 or female portion 604 of a stinger 600. The electronic component apertures 502 may be located on the bottom surface 500 of the electronic component 300 within 3 inches of an area defined by a projection on the electronic component bottom surface 500, the projection being a profile of the electronic component lifting mechanism 100 in the second position on the top surface of the electronic component 300 transposed onto the bottom surface 500 of the electronic component 300 beneath the electronic component lifting mechanism 100. Alternatively, the apertures 502 may be located anywhere on the bottom surface 500. The apertures 402 on the main housing portion bottom surface 400 may preferably be adjacent to the apertures 502 on the electronic component bottom surface 500 when the electronic component 300 is installed within the main housing portion 302.

Adjacent aperture pairs including a main housing portion aperture 402 and an aligned electronic component aperture 502 may each comprise a male portion 602 and a female portion 604 of a stinger 600 such that when the electronic component 300 is installed within the main housing portion 302, the male portion 602 and female portion 604 mechanically couple.

The main housing portion bottom surface 400 and the electronic component bottom surface 500 may preferably have a quantity of adjacent aperture pairs in the range of 4 to 10, more preferably in the range of 6 to 8. The electronic component apertures 502 may all contain female portions 604, while the main housing portion apertures 402 may contain all male portions 602. Alternatively, the electronic component apertures 502 may all contain male portions 602, while the main housing portion apertures 402 may contain all female portions 604. Alternatively still, a first quantity of the electronic component apertures 502 may contain female portions 604 and a second quantity of electronic component apertures 502 may contain male portions 602, while the main housing apertures 402 aligned with the first quantity of electronic component apertures 502 contain female portions 604 and main housing portion apertures 402 aligned with the second quantity of electronic component apertures 502 contain male portions 602.

As shown in FIG. 6, the male portion 602 may include a projection 606 and the female portion 604 may include a cavity 608. When the male portion 602 and the female portion 604 are mechanically coupled, the projection 606 is engaged within cavity 608.

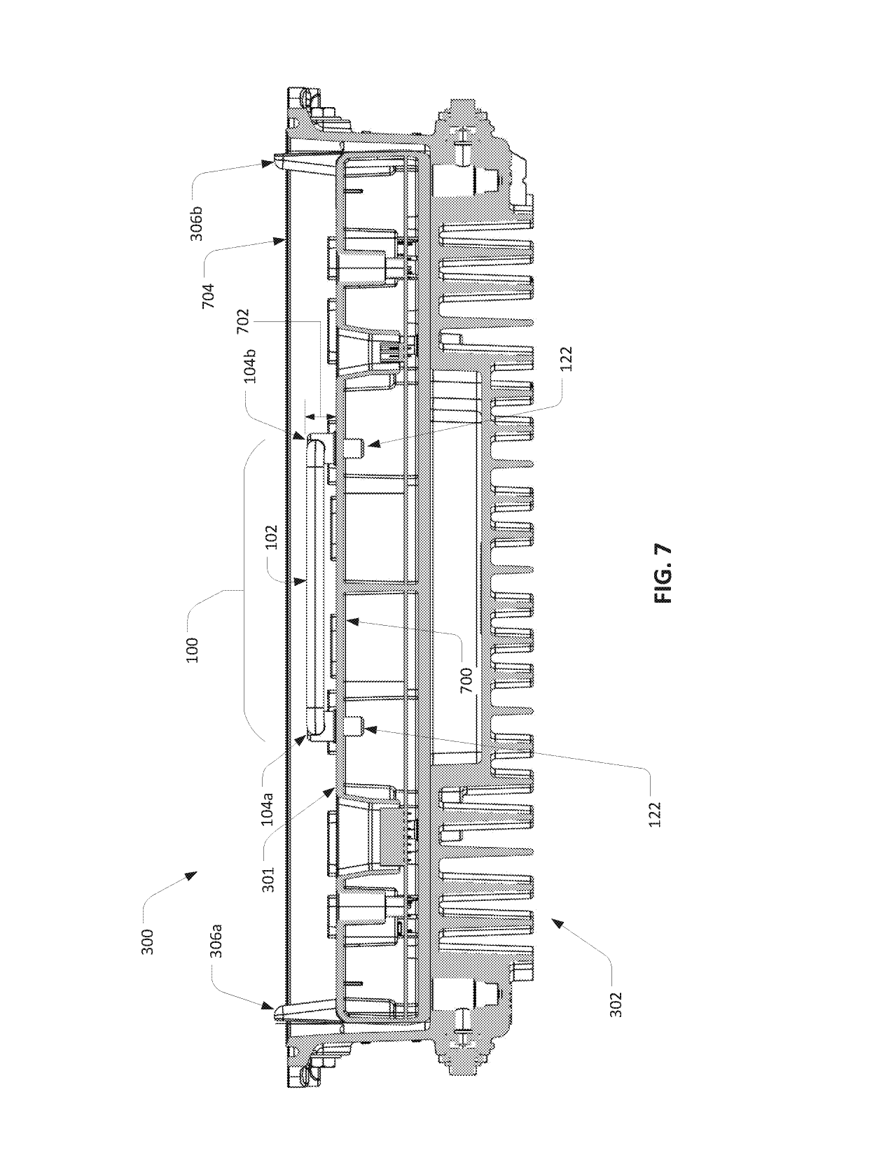

FIG. 7 depicts a cross section of the electronic component 300 where electronic component lifting mechanism 100 has been installed on the top surface 301. As discussed above, the shafts 122 of the connectors 104a, 104b are inserted into the top surface 301 such that a portion of the shafts 122 protrudes beyond the bottom face 700 of the top surface 301. The shafts 122 are shown in FIG. 7 without any retaining ring 112 or nut 114 to allow an unobscured view of the shafts 122.

Additionally, FIG. 7 depicts where pry features 306a, 306b protrude above the upper edge 704 of the main housing portion 302 to allow the user access when then electronic component 300 is installed within the main housing portion 302. On the other hand, the height 702 of the handle 102 in the second position, is configured to ensure no portion of the handle protrudes above the upper edge 704 of the main housing portion 302.

According to the present disclosure, there is thus provided an electronic component lifting mechanism comprising a handle having a central portion, a first end and a second end, the handle having a longitudinal midplane; and one or more connectors pivotally coupled to the first and second ends along a rotational axis, the one or more connectors fixedly coupled to a top surface of an electronic component; wherein the midplane contains the rotational axis; wherein the handle is configured to move between a first position and a second position, the handle being in the first position when the angle between the top surface of the electronic component and the midplane of the handle is in the range of 70° to 100°, and the handle being in the second position when the angle between the top surface of the electronic component and the midplane of the handle is in the range of -10° to 10°.

According to another embodiment of the present disclosure, there is thus provided an electronic device comprising a housing having a main housing portion and a hinged lid portion; an electronic component installed within the main housing portion; and an electronic component lifting mechanism, comprising a handle having a central portion, a first end and a second end, the handle having a longitudinal midplane, and one or more connectors pivotally coupled to the first and second ends along a rotational axis, the one or more connectors fixedly coupled to a top surface of the electronic component; wherein the midplane contains the rotational axis; wherein the handle is configured to move between a first position and a second position, the handle being in the first position when the angle between the top surface of the electronic component and the midplane of the handle is in the range of 70° to 100°, and the handle being in the second position when the angle between the top surface of the electronic component and the midplane of the handle is in the range of -10° to 10°.

Unless otherwise stated, use of the word "substantially" may be construed to include a precise relationship, condition, arrangement, orientation, and/or other characteristic, and deviations thereof as understood by one of ordinary skill in the art, to the extent that such deviations do not materially affect the disclosed methods and systems. The term “coupled" as used herein refers to any connection, coupling, link, or the like by which signals carried by one system element are imparted to the "coupled" element. Such “coupled" devices, or signals and devices, are not necessarily directly connected to one another and may be separated by intermediate components or devices that may manipulate or modify such signals. Likewise, the terms “connected” or “coupled” as used herein in regard to mechanical or physical connections or couplings is a relative term and does not require a direct physical connection. Elements, components, modules, and/or parts thereof that are described and/or otherwise portrayed through the figures to communicate with, be associated with, and/or be based on, something else, may be understood to so communicate, be associated with, and or be based on in a direct and/or indirect manner, unless otherwise stipulated herein.

Throughout the entirety of the present disclosure, use of the articles "a" and/or "an" and/or "the" to modify a noun may be understood to be used for convenience and to include one, or more than one, of the modified noun, unless otherwise specifically stated. The terms "comprising", "including" and "having" are intended to be inclusive and mean that there may be additional elements other than the listed elements. The phrase “at least one of A and B” should be understood to mean “only A, only B, or both A and B.”

Spatially relative terms, such as “beneath,” below,” upper,” “lower,” “above”, “left”, “right” and the like may be used herein for ease of description to describe one element or feature’s relationship to another element(s) or feature(s) as illustrated in the drawings. These spatially relative terms are intended to encompass different orientations of the device in use or operation in addition to the orientation shown in the drawings. For example, if the device in the drawings is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

Although the terms “first,” “second,” “third” etc. may be used to describe various elements, components, regions, layers and/or sections, these elements, components, regions, layers and/or sections are not to be limited by these terms as they are used only to distinguish one element, component, region, layer or section from another element, component, region, layer or section. Thus, a first element, component, region, layer, or section could be termed a second element, component, region, layer, or section without departing from the scope and teachings of the present invention.

While the principles of the invention have been described herein, it is to be understood by those skilled in the art that this description is made only by way of example and not as a limitation as to the scope of the invention. Other embodiments are contemplated within the scope of the present invention in addition to the exemplary embodiments shown and described herein. Modifications and substitutions by one of ordinary skill in the art are considered to be within the scope of the present invention, which is not to be limited except by the following claims.

What is claimed is:

1. An electronic component lifting mechanism comprising:
a handle having a central portion, a first end and a second end, the handle having a longitudinal midplane; and
one or more connectors pivotally coupled to the first and second ends along a rotational axis, the one or more connectors fixedly coupled to a top surface of an electronic component;
wherein the midplane contains the rotational axis;
wherein the handle is configured to move between a first position and a second position, the handle being in the first position when an angle between the top surface of the electronic component and the midplane of the handle is in the range of 70° to 100°, and the handle being in the second position when the angle between the top surface of the electronic component and the midplane of the handle is in the range of -10° to 10°.

2. The electronic component lifting mechanism of claim 1, wherein the handle is in the first position when the angle between the top surface of the electronic component and the midplane of the handle is in the range of 80° to 100°, and the handle is in the second position when the angle between the top surface of the electronic component and the midplane of the handle is in the range of -10° to 10°.

3. The electronic component lifting mechanism of claim 1, wherein the connectors include a connector hub having a front stop and a back stop, the front stop being configured to prevent the handle from rotating beyond the first position and the second stop being configured to prevent the handle from rotating beyond the second position.

4. The electronic component lifting mechanism of claim 1, wherein the connectors include a nut and a threaded shaft configured to be inserted into a hole in the top surface of an electronic component such that a portion of the shaft protrudes beyond a bottom face of the top surface, wherein the nut is installed on the portion of the shaft protruding beyond the bottom face.

5. An electronic device comprising:
a housing having a main housing portion and a hinged lid portion;
an electronic component installed within the main housing portion; and
an electronic component lifting mechanism, comprising:
a handle having a central portion, a first end and a second end, the handle having a longitudinal midplane; and
one or more connectors pivotally coupled to the first and second ends along a rotational axis, the one or more connectors fixedly coupled to a top surface of the electronic component;
wherein the midplane contains the rotational axis;
wherein the handle is configured to move between a first position and a second position, the handle being in the first position when an angle between the top surface of the electronic component and the midplane of the handle is in the range of 70° to 100°, and the handle being in the second position when the angle between the top surface of the electronic component and the midplane of the handle is in the range of -10° to 10°.

6. The electronic device of claim 5, wherein the handle is in the first position when the angle between the top surface of the electronic component and the midplane of the handle is in the range of 80° to 100°, and the handle is in the second position when the angle between the top surface of the electronic component and the midplane of the handle is in the range of -10° to 10°.

7. The electronic device of claim 5, wherein the connectors include a connector hub having a front stop and a back stop, the front stop being configured to prevent the handle from rotating beyond the first position and the second stop being configured to prevent the handle from rotating beyond the second position.

8. The electronic device of claim 5, wherein the connectors include a nut and a threaded shaft configured to be inserted into a hole in the top surface of an electronic component such that a portion of the shaft protrudes beyond a bottom face of the top surface, wherein the nut is installed on the portion of the shaft protruding beyond the bottom face.

9. The electronic device of claim 5, wherein the electronic component includes one or more prying features, wherein a portion of the prying features protrudes above an upper edge of the housing portion when the electronic component is installed within the housing portion.

10. The electronic device of claim 5, wherein the electronic component lifting mechanism is centered between two opposing lateral edges of the electronic component top surface and biased towards a third lateral edge of the electronic component top surface.

11. The electronic device of claim 5, wherein the electronic component includes a bottom surface having a quantity of apertures and the main housing portion includes a bottom surface having the same quantity of apertures,
wherein the apertures on the main housing portion align with the apertures of the electronic component when the electronic component is installed within the main housing portion,
wherein each aligned pair of apertures contains a male portion of a stinger connector and a female portion of a stinger, the male portion of the stinger configured to mate with the female portion of the stinger when the electronic component is installed within the housing portion.

12. The electronic device of claim 11, wherein the electronic component and the main housing portion each contain a quantity of apertures contain male and female portions of a stinger connector in the range of 6 to 8.

13. The electronic device of claim 11, wherein the apertures on the bottom surface of the electronic component are located within 3 inches of an area defined by a projection on the bottom surface of the electronic component, the projection being a profile of the electronic component lifting mechanism in the second position on the top surface of the electronic component transposed onto the bottom surface of the electronic component beneath the electronic component lifting mechanism.
